(19) United States
(12) Patent Application Publication
(10) Pub. No.: US 2011/0245411 A1
(43) Pub. Date: Oct. 6, 2011

(54) METHOD FOR PRODUCING SPRAYABLE LACQUER

(75) Inventors: John Charles Larson, West Chester, PA (US); Robert John Barsotti, Franklinville, NJ (US); Laura Ann Lewin, Greenville, DE (US)

(73) Assignee: E.I. DU PONT DE NEMOURS AND COMPANY, WILMINGTON (DE)

(21) Appl. No.: 13/132,662

(22) PCT Filed: Dec. 23, 2009
(86) PCT No.: PCT/US09/69362

§ 371 Date: Jun. 3, 2011

(30) Foreign Application Priority Data
Dec. 23, 2008 (US) 12/342133

(51) Int. Cl. C09D 133/00; C23C 16/448; C09D 175/04; C09D 167/00

(52) U.S. Cl. 524/556; 427/255.25; 524/589; 524/599

(57) ABSTRACT

The present invention is directed to a method for producing a sprayable composition on a substrate. The method comprises a step of introducing a crosslinking component into an atomized stream of a lacquer composition to improve the physical properties of an applied layer of lacquer composition while maintaining the excellent pot life properties. This invention is also directed to a delivery device and a system for introducing the catalyst into the atomized coating composition.

### FIELD OF INVENTION

The present invention is directed to a painting operation and method for producing a layer of a coating composition on a substrate using a spray gun. This spray-applied mixture subsequently forms a durable protective coating on a substrate.

### BACKGROUND OF INVENTION

The typical finish on an automotive substrate comprises an electrodeposited primer layer, an optional primer or primer surfacer layer over the electrodeposited primer layer and then a pigmented basecoat layer and a clearcoat layer is applied. A pigmented monocoat may be used in place of the basecoat/clearcoat layers. A number of clear and pigmented lacquers have been developed as automotive original equipment manufacture (OEM) and automotive refinish coatings, such as, for example, primers, basecoats and clearcoats but none meet the rapid drying times that are desired in combination with outstanding physical properties, such as, chip resistance, humidity resistance and adhesion.

Lacquers are useful compositions from an ease of use standpoint. Because lacquer compositions do not contain crosslinking components, they have a pot life that is measured in days or weeks. However, they tend to lack the same levels of chip resistance that can be achieved when a crosslinked coating composition is used. Crosslinked coating compositions are known in the art and comprise film-forming components comprising crosslinkable components and crosslinking components.

While crosslinked coating compositions provide improved properties, they are more difficult to use as the coating compositions, once formed, have a limited pot life, measured in minutes or hours. Pot life is the time it takes for the viscosity of the composition to increase to such point where spraying becomes ineffective, generally up to a two-fold increase in viscosity. In spray technologies currently used in refinish shops, crosslinking coating compositions can be prepared by mixing multiple reactive components of a coating composition to form a pot mix prior to spraying. The pot mix is placed in a cup-like reservoir or container that is attached to a spraying device such as a spray gun. Due to the reactive nature of the multiple reactive components, the pot mix will start to react as soon as they are mixed together causing continued increase in viscosity of the pot mix. Once the viscosity reaches a certain point, the pot mix becomes practically un-sprayable. The possibility that the spray gun itself may become clogged with crosslinked polymer materials is also disadvantageous.

Various methods of extending the pot life of a crosslinkable composition are known and can be used. One way to extend “pot life” is to add a greater amount of thinning solvent, also known as thinning agent, to the pot mix. However, thinning agent, such as organic solvent, contributes to increased emissions of volatile organic compounds (VOC) and also increases the curing time.

Other attempts to extend “pot life” of a pot mix of a coating composition have focused on “chemical-based” solutions. For example, it has been suggested to include modifications of one or more of the reactive components or certain additives that would retard polymerization reaction of the multiple components in the pot mix. The modifications or additives must be such that the rate of curing is not adversely affected after the coating is applied to the surface of a substrate.

Another approach is to mix one or more key components, such as a catalyst, together with other components of the coating composition immediately prior to spraying. One example is described in U.S. Pat. No. 7,201,289 in that a catalyst solution is stored in a separate dispenser and being dispensed and mixed with a liquid coating formulation before the coating formulation is atomized.

Yet another approach is to separately atomize two components, such as a catalyst and a resin, of a coating composition, and mix the two atomized components after spray. One such example is described in U.S. Pat. No. 4,824,017. However, such approach requires atomization of two components separately by using separate pumps and injection means for each of the two components.

### STATEMENT OF THE INVENTION

The present disclosure is directed to a painting operation and a method for producing a layer of a coating composition on a substrate using a spray gun, said method comprising the steps of:
(A) producing a first atomized stream comprising a lacquer composition through an orifice of said spray gun with a stream of a pressurized carrier, wherein said lacquer composition is stored in a first storage container and conveyed through a first inlet of said spray gun to said orifice;
(B) producing a second atomized stream comprising a crosslinking component, wherein the second atomized stream is produced by siphoning the crosslinking component with a siphoning stream selected from the first atomized stream of the lacquer composition, the stream of the pressurized carrier, or a combination thereof, from at least one delivery outlet coupled to a second storage container containing said crosslinking component, said delivery outlet being positioned at said orifice;
(C) optionally, regulating the supply of the crosslinking component to said delivery outlet by coupling a regulatory device to said delivery outlet;
(D) intermixing the first atomized stream and the second atomized stream to form a coating mixture; and
(E) applying the coating mixture on the substrate to form the layer of said coating composition thereon.
The present disclosure also relates to a method for producing a layer of a coating composition on a substrate using a spray gun, said method comprising the steps of:
   (A) producing a first atomized stream comprising or consisting essentially of a lacquer composition through an orifice of said spray gun with a stream of a pressurized carrier, wherein said lacquer composition is stored in a first storage container;
   (B) producing a second atomized stream of a second coating component, wherein the second atomized stream is produced by siphoning the second coating component with a siphoning stream selected from the first atomized stream of the lacquer composition, the stream of the pressurized carrier, or a combination thereof, from at least one first delivery outlet of a delivery device coupled to a second storage container containing said second component, said first delivery outlet being positioned at said orifice;
   (C) optionally, regulating the supply of the second coating component to said first delivery outlet by coupling a first regulatory device to said first delivery outlet;
   (D) producing a subsequent atomized stream of a subsequent component, wherein the subsequent atomized stream is produced by siphoning the subsequent coating component with the siphoning stream from at least one subsequent delivery outlet coupled to a subsequent storage container containing said subsequent component, said subsequent delivery outlet being positioned at said orifice;
   (E) optionally, regulating the supply of the subsequent coating component to said subsequent delivery outlet by coupling a subsequent regulatory device to said subsequent delivery outlet;
   (F) intermixing the first atomized stream, the second atomized stream and the subsequent atomized stream to form a coating mixture; and
   (G) applying the coating mixture on the substrate to form the layer of said coating composition thereon;
   wherein at least one of the second or subsequent coating component comprises or consists essentially of a crosslinking component.

### BRIEF DESCRIPTION OF DRAWING

FIG. 1 shows a spray gun affixed with an example of a representative delivery device of this invention.

FIG. 2 shows frontal views of the delivery device viewed from the direction 2A indicated in FIG. 1. (A) A schematic presentation of a representative example of the delivery device 2D constructed as an add-on device. (B) A schematic presentation of a representative example of the delivery device 2′ having one delivery outlet constructed into the air cap of the spray gun. (C) A schematic presentation of a representative example of the delivery device 2″ having two delivery outlets constructed into the air cap of the spray gun. (D) A schematic presentation of a representative example of the delivery device 2′″ having three delivery outlets (14) constructed into the air cap of the spray gun.

FIG. 3 shows an enlarged frontal view, in a schematic presentation, of a representative example of the delivery device 2D constructed as an add-on device that can be affixed to an air cap of a spray gun. A single intake coupling (8) is shown.

FIG. 4 shows an enlarged frontal view, in a schematic presentation, of another representative example of the delivery device 2D′ constructed as an add-on device that can be affixed to an air cap of a spray gun. Two intake couplings (8) are shown.

FIG. 5 shows an enlarged frontal view of details of the delivery device and the relative position of the delivery device and the orifice of the spray gun. Two delivery outlets (14), two connection paths (11) and one orifice (13) are shown. The arrows 6 indicate the direction of a cross-sectional view used in FIGS. 6, 7 and 8.

FIG. 6 shows an enlarged side cross sectional view of details of one example of the delivery device and the relative position of the delivery device and the orifice of the spray gun. The orifice (13) can be positioned in three different regions indicated with a, b and c, respectively.

FIG. 7 shows schematic presentations of examples of the formation of a coating mixture. (A) An example of a lacquer composition that is atomized at an orifice of a spray gun without the introduction of a second coating component. (B) An example of the coating mixture formed by an atomized lacquer and an atomized second coating component.

FIG. 8 shows schematic presentations of another example of the formation of a coating mixture. (A) A lacquer atomized at an orifice of a spray gun without the introduction of a second coating component. (B) A coating mixture formed by an atomized lacquer and an atomized second coating component.

FIG. 9 shows additional examples of the delivery device of this invention constructed as an add-on device. (A) An example of the delivery device that has a configuration of two intake couplings (8) and two delivery outlets (14). (B) An example of the delivery device that has a configuration of two intake couplings (8) and one common delivery outlet (14). The orifice (13) is shown in the figure to indicate relative position of the delivery device when affixed to the air cap. The orifice (13) is part of the spray gun.

FIG. 10 shows schematic presentations of different configurations of the delivery device of this invention. (A) An example of a delivery device having one intake coupling that is coupled to one storage container. (B) An example of a delivery device having one intake coupling that is coupled to two individual storage containers. (C) An example of a delivery device having two intake couplings that are coupled to two storage containers. (D) An example of a delivery device having three intake couplings that all three of them are coupled to a single storage container. (E) An example of a delivery device having three intake couplings that one of them is coupled to an individual storage container while other two are coupled to a single container. (F) Another example of a delivery device having three intake couplings that only one of them is coupled to a single storage container. (G) Another example of a delivery device having three intake couplings that two of them are coupled to a single storage container. (H) Another example of a delivery device having three intake couplings that each of the first and the second is coupled to an individual storage container while the third is not coupled to any container. The schematic representations are for illustration purposes only and items in the presentations may not be to scale. The orifice (13) is part of the spray gun.

FIG. 11 shows an example of another representative configuration.

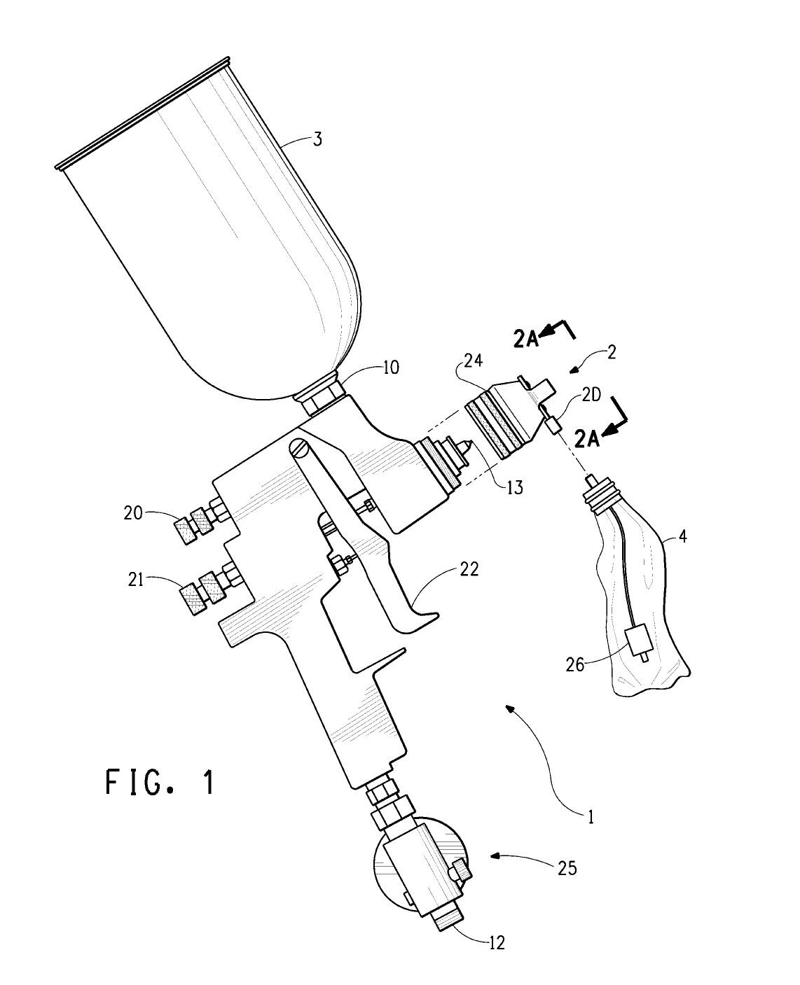

### DETAILED DESCRIPTION

The features and advantages of the present invention will be more readily understood, by those of ordinary skill in the art, from reading the following detailed description. It is to be appreciated that certain features of the invention, which are, for clarity, described above and below in the context of separate embodiments, may also be provided in combination in a single embodiment. Conversely, various features of the invention that are, for brevity, described in the context of a single embodiment, may also be provided separately or in any sub-combination. In addition, references in the singular may also include the plural (for example, “a” and “an” may refer to one, or one or more) unless the context specifically states otherwise.

The use of numerical values in the various ranges specified in this application, unless expressly indicated otherwise, are stated as approximations as though the minimum and maximum values within the stated ranges were both proceeded by the word “about”. In this manner, slight variations above and below the stated ranges can be used to achieve substantially the same results as values within the ranges. Also, the disclosure of these ranges is intended as a continuous range including every value between the minimum and maximum values.

As used herein:

The terms “lacquer” or “lacquer composition” mean a coating composition that is capable of drying by solvent evaporation to form a durable coating on a substrate. The lacquer compositions used herein comprise any of the known lacquer compositions having crosslinkable functional groups such as, for example, hydroxyl groups, amine groups, carboxyl groups, epoxy groups or combinations thereof. These groups are typically used to provide hydrogen bonding groups to improve the physical properties of the dried lacquer composition. Lacquer compositions according to the present disclosure can be solventborne lacquers or waterborne lacquers.

The present disclosure provides a method to apply a lacquer composition wherein an effective amount of a crosslinking component can be added during the spraying operation to improve the physical properties of the applied coating composition, such as, for example, humidity resistance, chipping resistance and adhesion. As the crosslinking component is not added directly to the lacquer composition until spray application, the pot life advantages of the lacquer are not impacted.

One embodiment of the disclosure is directed to a painting operation and a method for producing a layer of a coating composition on a substrate using a spray gun. The method can comprise the following steps:
(A) producing a first atomized stream comprising or consisting essentially of a lacquer composition through an orifice of said spray gun with a stream of a pressurized carrier, wherein said lacquer composition is stored in a first storage container and conveyed through a first inlet of said spray gun to said orifice;
(B) producing a second atomized stream comprising or consisting essentially of a crosslinking component, wherein the second atomized stream is produced by siphoning the crosslinking component with a siphoning stream selected from the first atomized stream of the lacquer composition, the stream of the pressurized carrier, or a combination thereof, from at least one delivery outlet coupled to a second storage container containing said crosslinking component, said delivery outlet being positioned at said orifice;
(C) optionally, regulating the supply of the crosslinking component to said delivery outlet by coupling a regulatory device to said delivery outlet;
(D) intermixing the first atomized stream and the second atomized stream to form a coating mixture; and
(E) applying the coating mixture on the substrate to form the layer of said coating composition thereon.

In another embodiment, the method comprises the steps of
(A) producing a first atomized stream comprising or consisting essentially of a lacquer composition through an orifice of said spray gun with a stream of a pressurized carrier, wherein said lacquer composition is stored in a first storage container;
(B) producing a second atomized stream of a second coating component, wherein the second atomized stream is produced by siphoning the second coating component with a siphoning stream selected from the first atomized stream of the lacquer composition, the stream of the pressurized carrier, or a combination thereof, from at least one first delivery outlet of a delivery device coupled to a second storage container containing said second component, said first delivery outlet being positioned at said orifice;
(C) optionally, regulating the supply of the second coating component to said first delivery outlet by coupling a first regulatory device to said first delivery outlet;
(D) producing a subsequent atomized stream of a subsequent component, wherein the subsequent atomized stream is produced by siphoning the subsequent coating component with the siphoning stream from at least one subsequent delivery outlet coupled to a subsequent storage container containing said subsequent component, said subsequent delivery outlet being positioned at said orifice;
(E) optionally, regulating the supply of the subsequent coating component to said subsequent delivery outlet by coupling a subsequent regulatory device to said subsequent delivery outlet;
(F) intermixing the first atomized stream, the second atomized stream and the subsequent atomized stream to form a coating mixture; and
(G) applying the coating mixture on the substrate to form the layer of said coating composition thereon;
wherein at least one of the second or the subsequent coating components comprises or consists essentially of a crosslinking component.

Any spray gun that can produce a stream of atomized coating composition can be suitable for use with this method. A gravity feed spray gun is preferred. A gravity feed spray gun using a pressurized carrier as an atomization carrier is further preferred. The pressurized carrier can be selected from compressed air, compressed gas, compressed gas mixture, or a combination thereof. Typically, the pressurized carrier can be compressed air. Typically, a spray gun comprises a spray gun body (1), a nozzle assembly (2) including an orifice (13) and an air cap (24), a carrier coupling (12) for coupling to a source of a pressurized carrier, such as compressed air, an air regulator assembly (25) for regulating flow rate and pressure of the carrier, a coating flow regulator (21) for regulating the flow of the lacquer composition that is stored in a main reservoir also known as a first storage container (3), and a first inlet (10) coupling the spray gun (1) to the first storage container (3). The spray gun typically also includes additional controls such as a trigger (22) and a spray fan regulator (20) for regulating compressed air. In a typical gravity feed spray gun, the lacquer composition is typically not pressurized and stored in the first storage container (3) which is at atmosphere pressure. The lacquer composition can be conveyed to the orifice by gravity, siphoning, or a combination of gravity and siphoning. The pressurized carrier can be selected from compressed air, compressed gas, compressed gas mixture, or a combination thereof. Typically, the pressurized carrier is compressed air. Compressed gas, such as compressed nitrogen, compressed carbon dioxide, compressed fluorocarbon, or a mixture thereof, can also be used. The compressed carrier can also include gases produced from compressed liquids, solids, or reactions from liquids or solids.

Lacquer compositions comprise high molecular weight polymers having various functional groups that can provide hydrogen bonding interactions with one another to produce a coating composition. The lacquer composition can also comprise various additives such as, for example, rheology control agents, pigments, flow additives, light stabilizers or combinations thereof.

Polymers suitable to form lacquer compositions are well known in the art. Examples include, alkyds, highly branched polyesters, solvent responsive dispersions, high molecular weight linear, graft and branched acrylic polymers, acrylic lattices, waterborne polyurethanes, waterborne polyesters, waterborne acrylic polymers or combinations thereof.

The second and/or subsequent coating components include crosslinking components. As used herein, crosslinking components can include compounds, oligomers and/or polymers having functional groups including isocyanate, amine, ketimine, melamine, epoxy, carboxylic acid, anhydride and a combination thereof. The crosslinking component can have on an average 2 to 25, preferably 2 to 15, more preferably 2 to 7, and even more preferably 3 to 5 crosslinking groups per molecule.

At least one of the lacquer composition, the second or subsequent coating components can comprise a catalyst for the crosslinking reaction. Crosslinking catalysts are well known in the art and can include, for example, tin catalysts, dibutyl tin dilaurate, tin (II) octanoate, 1,4-diazabicyclo[2.2.2]octane, zinc octoate, triphenyl phosphine, quaternary ammonium compounds, strong bases, aluminum halides, alkyl aluminum halides or tertiary amines, such as, triethylenediamine, depending upon the crosslinkable and crosslinking functional groups. These catalysts can be used alone or in conjunction with carboxylic acids, such as, acetic acid. One example of commercially available catalysts is dibutyl tin dilaurate as FASCAT® series sold by Arkema, Bristol, Pa., under respective trademark. The amount of the catalyst depends upon the reactivity of functional groups. Generally, in the range of from about 0.001 percent to about 5 percent, preferably in the range of from 0.01 percent to 2 percent, more preferably in the range of from 0.02 percent to 1 percent, all in weight percent based on the total weight of the crosslinkable component solids.

Additionally, the lacquer, the second and/or the subsequent coating components can comprise other additives that are common to coating compositions. Suitable additives can include, for example, pigments, pigment dispersions, light stabilizers, crosslinking catalysts, rheology control agents, organic solvents, aqueous solvents, plasticizers, flow agents or combinations thereof.

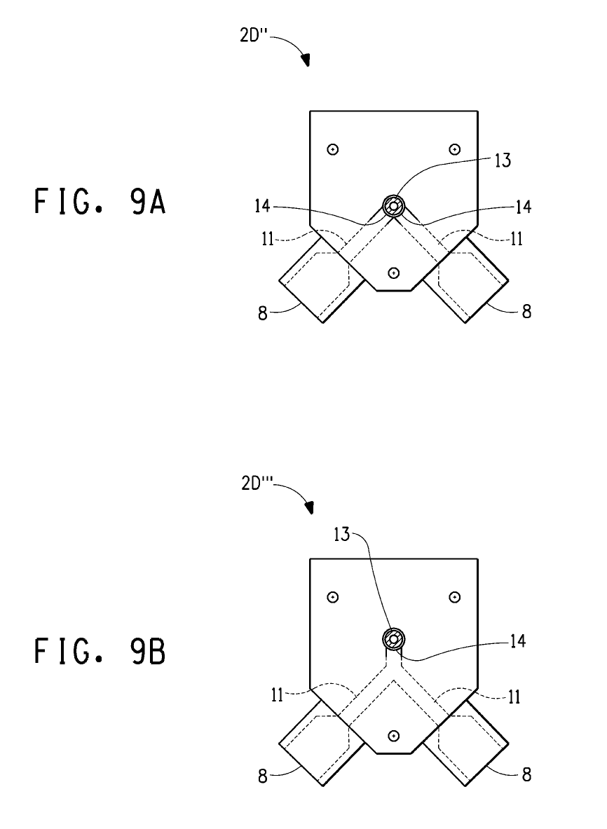

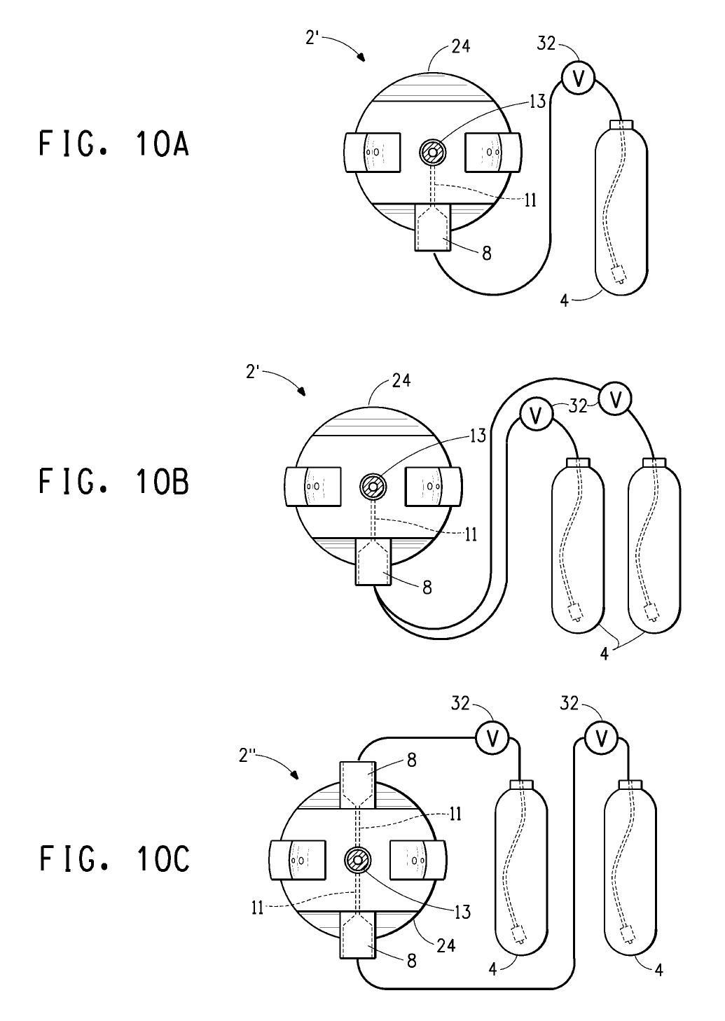

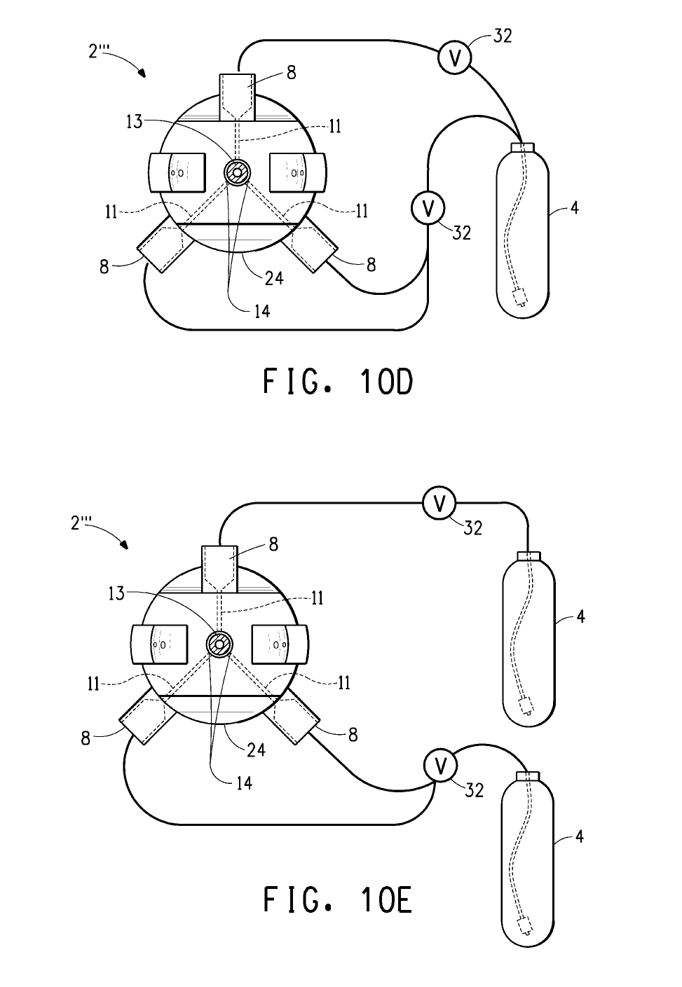

In the above embodiments, the one or more components of the second coating component can be siphoned separately such as in the configurations shown in FIGS. 9A, 10C, 10E or 10H. The one or more sub-components of the second coating component can be siphoned together such as in the configurations shown in FIG. 10B.

The second coating component can be siphoned from at least one delivery outlet (14) with a siphoning stream selected from the first atomized stream of the lacquer composition, the stream of the pressurized carrier, or a combination thereof. The delivery outlet is coupled to a second storage container containing said second component, said delivery outlet being positioned at said orifice. Said delivery outlet and said orifice can be positioned at any relative angles or relative positions such that the siphoning can effectively take place. While not wishing to be bound by any particular theory, “siphoning” is believed to occur when the siphoning stream is moving at high speed at the delivery outlet causing negative air pressure around the delivery outlet. Such negative air pressure is believed to cause the second coating component to be conveyed to the delivery outlet. High velocity of the stream of the pressurized carrier and sudden change in air pressure associated with the negative air pressure at the delivery outlet are believed to cause the second coating component to become atomized and intermixed into the siphoning stream and the first atomized stream of the lacquer composition. In this invention, the lacquer and the second coating components can be mixed at a pre-determined mixing ratio to form the coating mixture. The second coating component can also be conveyed to the delivery outlet by gravity or a combination of gravity and siphoning in certain embodiments of configurations disclosed herein.

Both the lacquer and the second coating component can be stored in respective storage containers at atmosphere pressure.

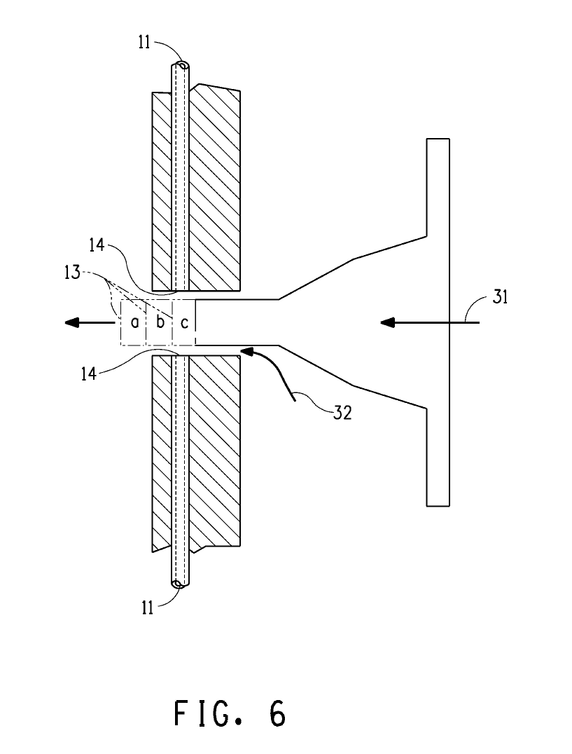

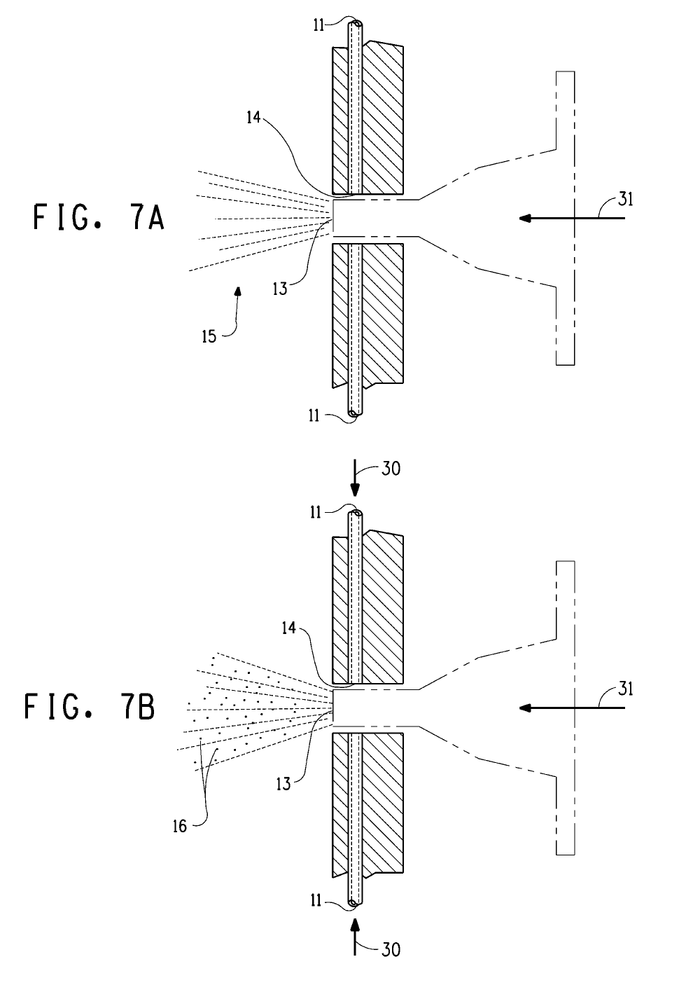

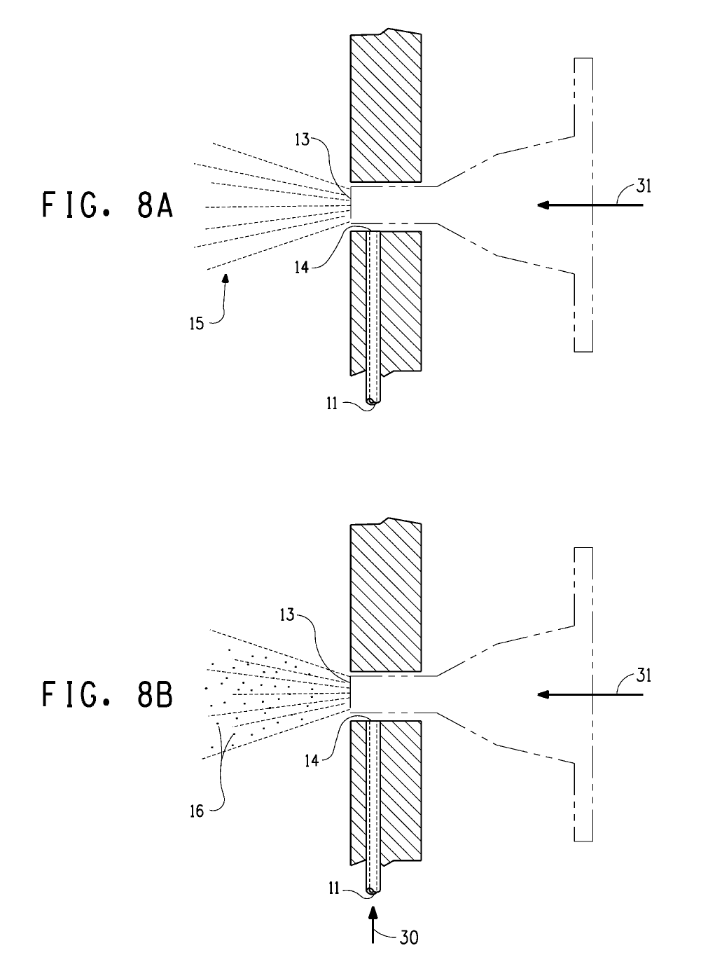

Depending upon the relative position between the orifice (13) and the delivery outlet (14), the second coating component can be siphoned with different siphoning stream. When the orifice is positioned in the position illustrated by the region 13a and 13b in FIG. 6, the second coating component can be siphoned primarily by the pressurized carrier moving at high speed in the direction shown by the arrow (32). FIG. 7 shows examples of a delivery device having two delivery outlets. FIG. 8 shows examples of a delivery device having one delivery outlet. The pressurized carrier then continues to produce atomized lacquer composition at the orifice (13). The atomized lacquer and second coating component can be intermixed to form the coating mixture (16) (FIGS. 7B and 8B). When the orifice is positioned in the position illustrated by the region 13c in FIG. 6, the second coating component can be siphoned primarily by a combination of the pressurized carrier moving at high speed in the direction shown by the arrow (32) and the first atomized stream of the lacquer composition. If the second coating component is not supplied to the delivery outlet, for example, if a regulatory device (32) is turned off, then only the lacquer composition is atomized (15) (FIGS. 7A and 8A). Flow of the lacquer composition is indicated by the arrow (31). Flow of the second coating component is indicated by the arrows (30).

The coating mixture can be applied over a substrate. Typically, a painter can hold the spray gun at a certain distance from the substrate and move it in desired directions so the coating mixture can be sprayed over the substrate forming a layer of the coating composition. This invention can further comprise the step of curing the layer of the coating composition on the substrate to form a coating thereon. This curing step can depend upon the coating composition used. The layer can be cured at ambient temperatures, or at elevated temperatures, such as up to 180° C.

The substrate can include wood, plastic, leather, paper, woven and nonwoven fabrics, metal, plaster, cementitious and asphaltic substrates, and substrates that have one or more existing layers of coating thereon. The substrate can be a vehicle, vehicle body, or vehicle body parts.

In another embodiment, the method to control the viscosity of a coating composition can comprise the steps of:
(A) producing a first atomized stream comprising or consisting essentially of a lacquer composition of said coating composition through an orifice of said spray gun with a stream of a pressurized carrier, wherein said lacquer composition is stored in a first storage container and conveyed through a first inlet of said spray gun to said orifice;
(B) producing a second atomized stream of a second coating component of said coating composition, wherein the second atomized stream is produced by siphoning the second coating component with a siphoning stream selected from the first atomized stream of the lacquer composition, the stream of the pressurized carrier, or a combination thereof, from at least one first delivery outlet of a delivery device coupled to a second storage container containing said second component, said first delivery outlet being positioned at said orifice;
(C) optionally, regulating the supply of the second coating component to said delivery outlet by coupling a first regulatory device to said first delivery outlet;
(D) producing a subsequent atomized stream of a subsequent component of said coating composition, wherein the subsequent atomized stream is produced by siphoning the subsequent coating component with the siphoning stream from at least one subsequent delivery outlet of the delivery device coupled to a subsequent storage container containing said subsequent component, said subsequent delivery outlet being positioned at said orifice;
(E) optionally, regulating the supply of the subsequent coating component to said subsequent delivery outlet by coupling a subsequent regulatory device to said subsequent delivery outlet;
(F) intermixing the first atomized stream, the second atomized stream and the subsequent atomized stream to form a coating mixture; and
(G) applying the coating mixture on the substrate to form the layer of said coating composition thereon; and
wherein at least one of the second or subsequent coating components comprises or consists essentially of a crosslinking component.

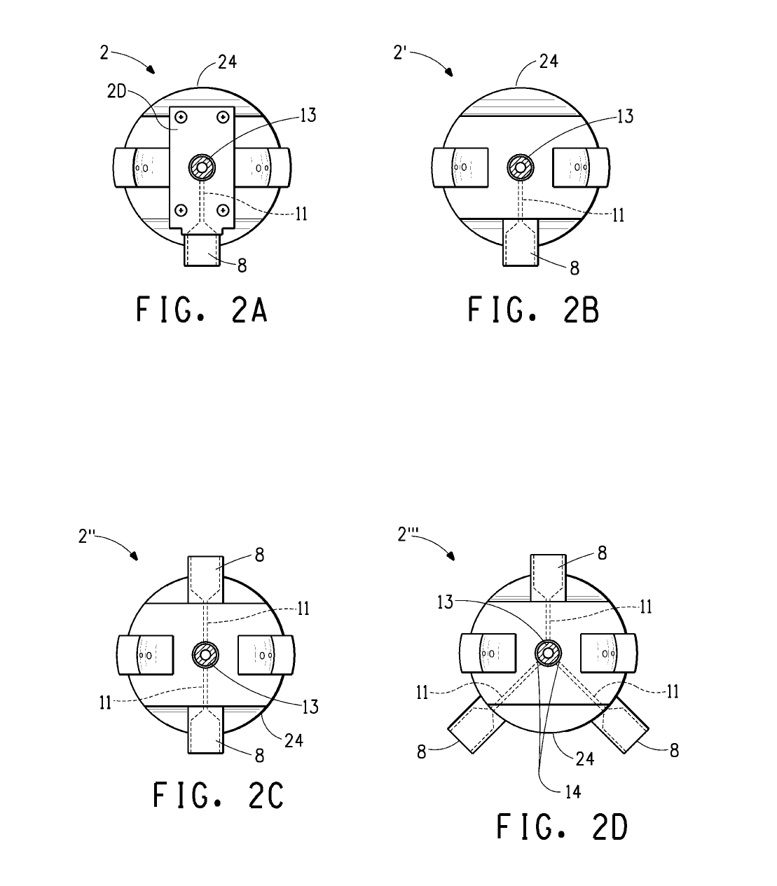

The first delivery outlet and the subsequent delivery outlet can be separate delivery outlets or combined into a single delivery outlet. FIGS. 2C, 2D, 4, 5, 6, 7, 9A show some examples of separate delivery outlets. FIG. 9B show one example where two delivery outlets can be combined into a single delivery outlet. Based on disclosure of this invention herein, more delivery outlets and/or different placement and positioning of delivery outlets can be configured by those skilled in the art without departing from the scope and spirit of this invention.

All the components, including the lacquer and the second coating component, and any subsequent component can be stored in respective storage containers at atmosphere pressure.

One advantage of this invention is that said atomized lacquer composition, said atomized second coating component, and any subsequent coating component if present, can be mixed at a pre-determined mixing ratio to form said coating mixture without the need for complex controls such as those described in aforementioned U.S. Pat. No. 4,824,017. The pre-determined mixing ratio can be determined by modulating or selecting the size of the delivery outlet (14), the size of connecting path (11), or by providing a regulatory device such as a flow rate controller functionally coupled to said delivery device, or a combination thereof. It can be configured that one regulatory device can regulate the flow rate of one or more delivery outlets. Mixing ratio can also be controlled by modulating the viscosity of the lacquer, the second or both the lacquer and the second coating components. In one example, viscosity of the second coating component can be increased to reduce the amount being siphoned into the coating mixture. In another example, viscosity of the second coating component can be reduced to increase the amount being siphoned into the coating mixture. Similarly, viscosity of the lacquer composition can be reduced or increased as needed to achieve a desired mixing ratio.

The applicants unexpectedly discovered that using the method of this invention, mixing ratio can be constant within a wide range of pressures of the pressurized carrier ranging from 20-80 pounds per square inch gauge (psig). In one example, pressure of the pressurized carrier can be in a range of from 25 to 70 psig. In another example, pressure of the pressurized carrier can be in a range of from 28 to 65 psig. In yet another example, pressure of the pressurized carrier can be in a range of from 30 to 60 psig.

In one example, the mixing ratio can be determined by selecting different sizes of the diameter of the delivery outlet. Coating mixtures formed by using different sizes of the outlets can be sprayed onto suitable substrates. Properties of the coating layers formed thereon can be measured. Based on the property measurement, a suitable size or a range of suitable sizes of the delivery outlets can be selected. In another example, the mixing ratio can be determined by selecting different size of diameter of the connection path.

The mixing ratio of the lacquer composition to the second or any subsequent coating component can range from 5/1 to 80/1. In one embodiments, the mixing ratio is in the range of from 8/1 to 40/1 and in another embodiment, the mixing ratio is in the range of from 10/1 to 20/1.

The regulatory device can be selected from a mechanical flow restrictor, an electric flow restrictor, a pressure controlled flow restrictor, an actuated pneumatic flow restrictor, or a combination thereof. Examples of a mechanical flow restrictor can include a tube with a pre-determined flow pass diameter that is coupled to the delivery outlet, or a mechanical valve that can control flow passage. Examples of an electronic flow restrictor can include electrical valves or a electrical valve actuator. A pressure controlled flow restrictor can be any mechanical or electric controllers that can control flow based on pressure.

A flow rate controller, such as a valve or a commercial inline flow controller can be coupled to the delivery outlet to adjust the flow of the second coating component therefore affecting mixing ratio. A flow rate controller can also be a small insert that is placed inside a connection path or a tubing connected to a connection path that is coupled to the delivery outlet. Such an insert can effectively reduce the size of the connection path or the tubing therefore reduces the flow of the second coating component.

Selection of sizes and the use of flow rate controller can be combined. For example, a size within a suitable range of the delivery outlet can be selected and a valve can be coupled to the delivery outlet so the mixing ratio can be fine tuned. Any flow rate controller that can be coupled to the delivery outlet can be suitable for this invention.

A regulatory device can be coupled to a delivery outlet at any places that can effectively regulate flow to that delivery outlet. The regulatory device can be coupled at an intake coupling or be placed in a connection path connecting to that particular delivery outlet. The regulatory device can also be placed at any place along a tubing that delivers the second or the subsequent coating component from its storage container to the intake coupling of the delivery device.

An advantage of this invention is to have the ability to cure a lacquer composition while maintaining extended pot life. The rate of curing can easily be varied by changing the ratio of the lacquer composition to the crosslinking component containing the crosslinking component.

Yet another advantage of this invention is that some aspects of spraying or the coating property can be modified in an on-demand fashion. For example, curing time of the coating composition can be modulated by modifying the amount of a catalyst mixed into the coating composition during spraying. It can be done by tuning the regulatory device while spraying.

This disclosure is further directed to a system for producing a sprayable lacquer. The system can comprise:
(A) a spray gun comprising a spray gun body (1), one or more inlets, a nozzle assembly (2) including an orifice (13) and an air cap (24); and
(B) a delivery device comprising:
   (i) at least one delivery outlet (14), wherein said delivery outlet being positioned at said orifice (13);
   (ii) at least one intake coupling (8); and
   (iii) at least one connection path (11) connecting said intake coupling (8) and said delivery outlet (14), wherein said delivery outlet is coupled through said connection path and said intake coupling to a storage container (4) containing a second coating component;
(C) optionally, a regulatory device (32) coupled to said delivery outlet regulating the supply of the second coating component to said delivery outlet;
wherein a first atomized stream of a lacquer composition of said coating composition is produced at said orifice (13) with a stream of a pressurized carrier, wherein said lacquer composition is stored in a first storage container and conveyed through a first inlet of said spray gun to said orifice;
wherein a second atomized stream of a second coating component of said coating composition is produced by siphoning the second coating component with a siphoning stream selected from the first atomized stream of the lacquer composition, the stream of the pressurized carrier, or a combination thereof, from said delivery outlet (14) coupled to a second storage container containing said second component; and
wherein the second coating component comprises a crosslinking component.

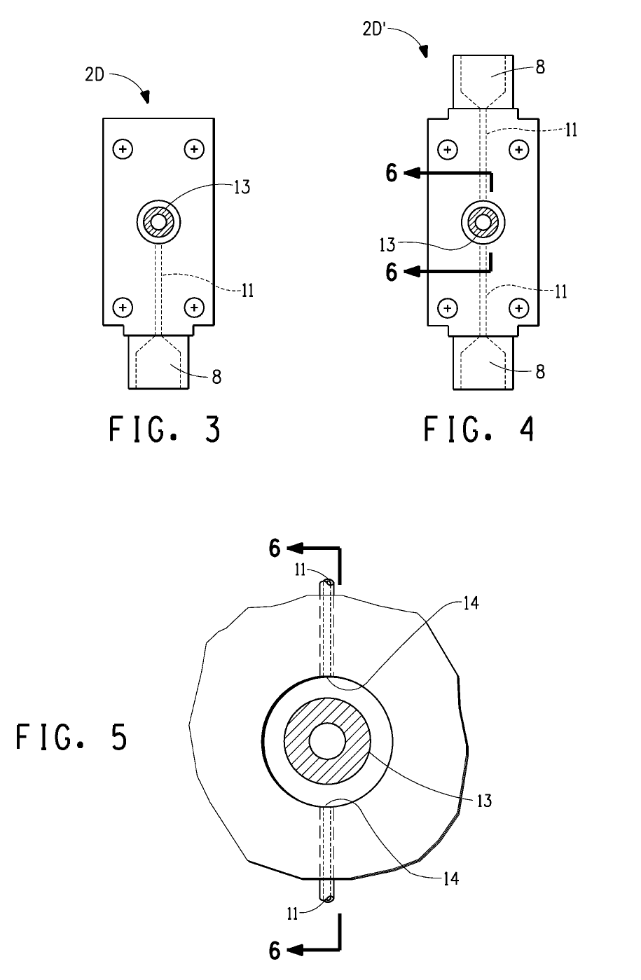

The delivery outlet (14), the intake coupling (8), and the connection path (11) can be constructed as an add-on device affixed to the air cap of the spray gun, or can be constructed into the air cap of said spray gun. Representative examples of the add-on device can include the ones shown in FIGS. 2A, 3, 4, 9A and 9B. The add-on device can be affixed to the air cap using conventional means such as one or more screws, clips, clamps, adhesives, latches, or a combination thereof. Examples of the delivery device constructed into the air cap can include those shown in FIGS. 2B, 2C and 2D. The delivery device can comprise one delivery outlet, such as those shown in FIGS. 2A, 2B and 3. The delivery device can also comprise two or more delivery outlets, such as those shown in FIGS. 2C, 2D, 4, and 9A. Two or more delivery outlets can be combined into a single delivery outlet, such as the one shown in FIG. 9B.

Representative configurations of the add-on device (2D) can be shown in FIGS. 2A, 3, 4, 9A, and 9B. The system can have a single delivery outlet (14), such as shown in FIGS. 2A, 3, and 9B; or two or more delivery outlets (14) as shown in FIGS. 4 and 9A. Based on descriptions disclosed herein, those skilled in the art can make modifications and re-configurations so the add-on device can be used with other spray guns, nozzle assemblies, air caps, or a combination thereof.

FIG. 5 shows an enlarged frontal view of the orifice (13) and two of the delivery outlets (14). FIG. 6 shows a cross sectional side view of the delivery device indicating the relative positions of two of the delivery outlets (14) and the orifice (13) wherein each of the delivery outlets (14) is positioned at said orifice (13). As described before, depending upon the relative position between the orifice (13) and the delivery outlet (14), the second (or a subsequent) coating component can be siphoned with different siphoning stream. Although perpendicular relative position is shown in the Figures and examples of this disclosure, the delivery outlet and the orifice can be positioned in any relative positions such that siphoning can effectively take place.

The system described herein can be configured to siphon a third or a subsequent component. A delivery device of this invention can be configured to have multiple intake couplings (8), multiple connection paths (11) or multiple delivery outlets (14) as shown in representative examples in FIGS. 2C, 2D, 4, 9A, and 9B. Other examples of configurations are shown in FIGS. 10A through 10H. In another representative configuration, two or more connection paths can be combined at a point so the connection paths are connected to a single delivery outlet (14), which can be positioned at the orifice (13). One example is shown in FIG. 9B.

The one or more intake couplings (8) can be configured to couple with one or more individual storage containers (4) through direct coupling, such as plug on or screwed on, or via connection means such as fixed or flexible tubing. Additional hardware such as one or more “Y” shaped connectors can also be used. Examples of suitable configurations are shown in FIG. 10: (A) a delivery device having a single delivery outlet/intake coupling that is coupled to a single container; (B) a delivery device having a single intake coupling that is coupled to two individual containers; (C) a delivery device having two outlets/intake couplings that are coupled to two individual containers (shown) or a single container (not shown); (D)-(H) a delivery device having multiple outlets and intake couplings that only some of them are coupled to one or more containers, wherein the other intake(s) can be closed. When a delivery device has two or more intake couplings and only one of them is coupled to a container, it is preferred to close the un-coupled intake couplings via conventional means, such as a cap, a plug, or a valve. Optionally, one or more regulatory devices (32) that controls flow rate, such as a valve, an insert, a clamp, or a commercial inline flow controller can be positioned and configured to control flow rate of one or more components at one or more positions. The regulatory device can be selected from a mechanical flow restrictor, an electric flow restrictor, a pressure controlled flow restrictor, or a combination thereof. Those skilled in the art can design or modify configurations based on the descriptions disclosed herein without departing from the spirit and scope of this invention.

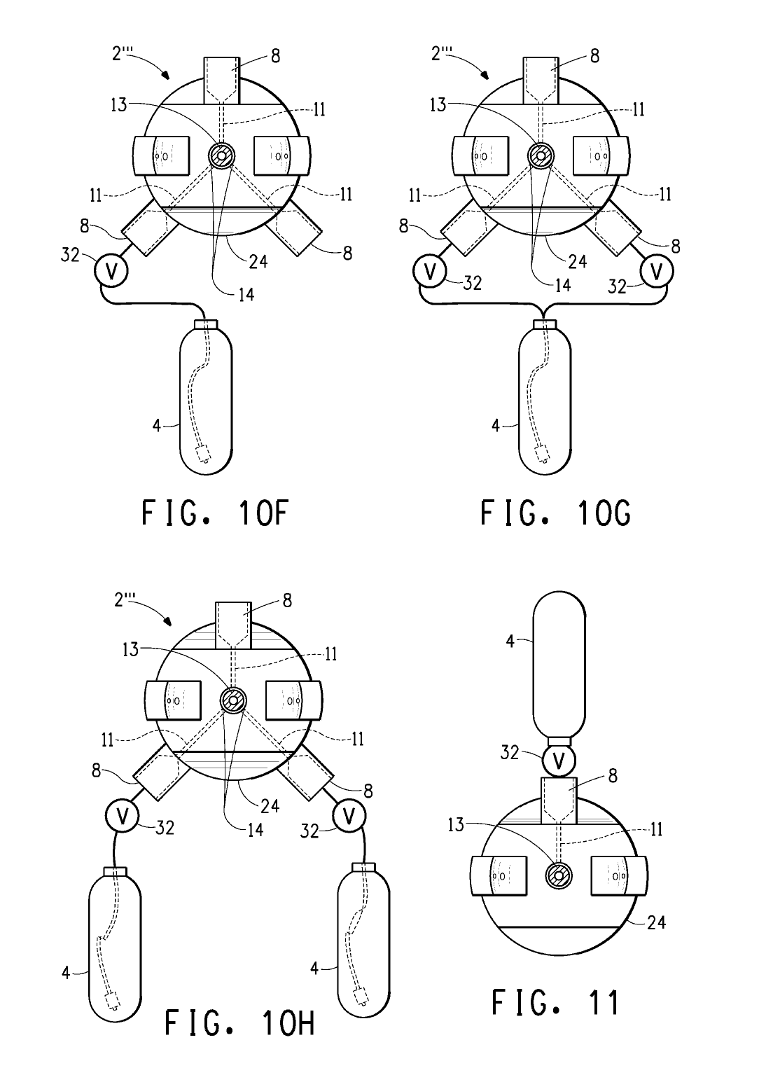

FIG. 11 shows an example of another representative configuration. In this example, the container (4) can be connected at the top of the intake coupling (8) via conventional connections, such as a screw connection or a plug-in connection. A regulatory device (32), such as a valve, can be placed in the path connecting the container (4) and the intake coupling (8). In one example, the regulatory device (32) is a valve has two coupling ends: one coupled to the intake coupling (8) and the other coupled to the container (4). In another example, the regulatory device (32) is a valve built in the container that can be coupled to the intake coupling (8). In yet another example, the regulatory device (32) is a valve built in the intake coupling (8) that can be coupled to the container (4). The regulatory device (32) can be turned on or off manually, or by connecting to the trigger (22) mechanically or electronically. It is preferred that the regulatory device (32) can be turned off when the spray gun is not spraying to prevent leaking of the contents in the container (4) and can be turned on to allow the content in the container (4) to flow to the delivery outlet (14).

The storage container (4) containing the second or a subsequent coating component can be a flexible container, such as a plastic bag; a fixed-shape container, such as a canister made of metal or hard plastic; or a flexible inner container inside a fixed-shape container, such as a flexible plastic bag placed inside a fixed-shape metal container. A flexible container that can be collapsed easily is preferred. The flexible container can be a collapsible liner that can be sealed and used directly or be placed inside a fixed shape container. The storage container can be transparent or have a transparent window so the level of the content in the container can be readily visible. The storage container can have an indicator to indicate the level of the contents in the container. The storage container can be disposable or reusable. The storage container can be coupled to an intake coupling (8) which is connected to the delivery outlet (14) through a connection path (11). The storage container can be coupled to the intake coupling (8) via conventional means, such as a clip, a clamp, a set of matching screw tracks, or a plug-in. In one example, the storage container comprises a tube that can be plugged into the intake coupling (8). In another example, the storage container is screwed onto the intake coupling (8) via matching screw tracks. In yet another example, the storage container is plugged into the intake coupling (8) and secured by an additional fastener. The storage container can further have a unidirectional flow limiter (26) to eliminate back flow, wherein said unidirectional flow limiter can only allow the content to flow in one direction, such as only from the container to the delivery outlet. Any back flow can be stopped by the directional flow limiter to avoid potential contamination. For a fixed-shape container, ventilation can be provided so the contents in the container can be maintained at atmosphere pressure.

What is claimed is:

1. In a painting operation, a method for producing a layer of a coating composition on a substrate using a spray gun, said method comprising the steps of:
(A) producing a first atomized stream comprising a lacquer composition through an orifice of said spray gun with a stream of a pressurized carrier, wherein said lacquer composition is stored in a first storage container and conveyed through a first inlet of said spray gun to said orifice;
(B) producing a second atomized stream comprising a crosslinking component, wherein the second atomized stream is produced by siphoning the crosslinking component with a siphoning stream selected from the first atomized stream of the lacquer composition, the stream of the pressurized carrier, or a combination thereof, from at least one delivery outlet coupled to a second storage container containing said crosslinking component, said delivery outlet being positioned at said orifice;
(C) optionally, regulating the supply of the crosslinking component to said delivery outlet by coupling a regulatory device to said delivery outlet;
(D) intermixing the first atomized stream and the second atomized stream to form a coating mixture; and
(E) applying the coating mixture on the substrate to form the layer of said coating composition thereon.

2. The method of claim 1, wherein the ratio of lacquer composition to crosslinking component is in the range of from 8/1 to 80/1.

3. The method of claim 1, wherein said crosslinking component is a compound, oligomer or polymer having on average 2 to 25 crosslinking functional groups per molecule selected from the group consisting of isocyanate, amine, ketimine, melamine, epoxy, carboxylic acid, anhydride, and a combination thereof.

4. The method of claim 3 wherein the crosslinking component is an isocyanate.

5. The method of claim 1 wherein the lacquer composition is a solventborne lacquer composition or a waterborne lacquer composition.

6. The method of claim 1, wherein said layer is a primer layer, a basecoat layer, a pigmented basecoat layer, a pigmented monocoat or a clearcoat layer.

7. The method of claim 1, wherein the second coating component comprises a crosslinking catalyst.

8. The method of claim 5, wherein said crosslinking catalyst is selected from the group consisting of tin catalysts, tertiary amines and a combination thereof.

9. The method of claim 1, wherein said second atomized stream is produced by siphoning the second coating component with the first atomized stream.

10. The method of claim 1, wherein said second atomized stream is produced by siphoning the second coating component with the stream of the pressurized carrier.

11. The method of claim 1, wherein said second atomized stream is produced by siphoning the second coating component with a combination of the first atomized stream and the stream of the pressurized carrier.

12. The method of claim 1, wherein said substrate is a vehicle, vehicle body, or vehicle body parts.

13. The method of claim 1, wherein said regulatory device is selected from a mechanical flow restrictor, an electric flow restrictor, a pressure controlled flow restrictor, or a combination thereof.

14. The method of claim 1 further comprising the step of curing said layer of said coating composition on the substrate to form a coating thereon.

15. A coating layer produced by the method of claim 1.

16. A coated substrate produced by the method of claim 1.

17. In a painting operation, a method for producing a layer of a coating composition on a substrate using a spray gun, said method comprising the steps of:
(A) producing a first atomized stream comprising a crosslinking component, wherein the second atomized stream is produced by siphoning the crosslinking component with a siphoning stream selected from the first atomized stream of the lacquer composition, the stream of the pressurized carrier, or a combination thereof, from at least one delivery outlet coupled to a second storage container containing said crosslinking component, said delivery outlet being positioned at said orifice;
(B) producing a second atomized stream of a second coating component of said coating composition, wherein the second atomized stream is produced by siphoning the second coating component with a siphoning stream selected from the first atomized stream of the lacquer composition, the stream of the pressurized carrier, or a combination thereof, from at least one first delivery outlet of a delivery device coupled to a second storage container containing said second component, said first delivery outlet being positioned at said orifice;
(C) optionally, regulating the supply of the second coating component to said first delivery outlet by coupling a first regulatory device to said first delivery outlet;
(D) producing a subsequent atomized stream of a subsequent component of said coating composition, wherein the subsequent atomized stream is produced by siphoning the subsequent coating component with the siphoning stream from at least one subsequent delivery outlet coupled to a subsequent storage container containing said subsequent component, said subsequent delivery outlet being positioned at said orifice;
(E) optionally, regulating the supply of the subsequent coating component to said subsequent delivery outlet by coupling a subsequent regulatory device to said subsequent delivery outlet;
(F) intermixing the first atomized stream, the second atomized stream and the subsequent atomized stream to form a coating mixture; and
(G) applying the coating mixture on the substrate to form the layer of said coating composition thereon;
wherein at least one of the second or subsequent coating component comprise a crosslinking component.

18. The method of claim 17, wherein said crosslinking component is a compound, oligomer or polymer having on average 2 to 25 crosslinking functional groups per molecule selected from the group consisting of isocyanate, amine, ketimine, melamine, epoxy, carboxylic acid, anhydride, and a combination thereof.

19. The method of claim 17, wherein the ratio of lacquer composition to crosslinking component is in the range of from 5/1 to 80/1

20. A coating layer produced by the method of claim 17.

21. A coated substrate produced by the method of claim 17.

22. The coated substrate of claim 18 wherein the crosslinking component is an isocyanate.
